(19) United States
(12) Patent Application Publication
(10) Pub. No.: US 2010/0248969 A1
(43) Pub. Date: Sep. 30, 2010

(54) OXIDE SUPERCONDUCTING WIRE, SUPERCONDUCTING STRUCTURE, METHOD OF PRODUCING OXIDE SUPERCONDUCTING WIRE, SUPERCONDUCTING CABLE, SUPERCONDUCTING MAGNET, AND PRODUCT INCORPORATING SUPERCONDUCTING MAGNET

(75) Inventors: Jun Fujikami, Osaka (JP); Naoki Ayai, Osaka (JP); Takeshi Kato, Osaka (JP); Shin-ichi Kobayashi, Osaka (JP)

Correspondence Address: DRINKER BIDDLE & REATH (DC), 1500 K STREET, N.W., SUITE 1100, WASHINGTON, DC, 20005-1209, US

(73) Assignee: Sumitomo Electric Industries, Ltd., Osaka-shi (JP)

(21) Appl. No.: 12/160,353

(22) PCT Filed: Aug. 8, 2007
(86) PCT No.: PCT/JP2007/065487

§ 371 Date: Jul. 9, 2008

(30) Foreign Application Priority Data
Jan. 11, 2007 (JP) 2007-003724

(51) Int. Cl. H01B 12/08; H01L 39/24; H01L 39/08; H01F 6/06; G01R 33/3815; H01B 1/20; H01B 7/08

(52) U.S. Cl. 505/166; 505/231; 505/431; 505/211; 324/318; 174/98; 174/117 F

(57) ABSTRACT

The invention offers an oxide superconducting wire, a superconducting structure, a method of producing an oxide superconducting wire, a superconducting cable, a superconducting magnet, and a product incorporating the superconducting magnet. The oxide superconducting wire is a tape-shaped oxide superconducting wire in which a plurality of filaments, each of which has a Bi-2223-based oxide superconductor, are embedded in a matrix. The oxide superconducting wire has a cross-sectional area of at most 0.5 mm² in a cross section perpendicular to the direction of its length. In the cross section of the oxide superconducting wire, the filaments have an average cross-sectional area per filament of at least 0.2% and at most 6% of the cross-sectional area of the oxide superconducting wire. Having the above features, the oxide superconducting wire can not only increase its critical current density but also decrease its AC loss.

### TECHNICAL FIELD

The present invention relates to an oxide superconducting wire, a superconducting structure, a method of producing an oxide superconducting wire, a superconducting cable, a superconducting magnet, and a product incorporating the superconducting magnet.

### BACKGROUND ART

An oxide superconducting wire incorporating a Bi-2223-based oxide superconductor has been expected as a materiel to be used, for example, in a superconducting cable, a superconducting magnet, and a product incorporating the superconducting magnet. The reason is that the wire can be used at the liquid nitrogen temperature, achieves a relatively high critical current density, and is relatively easy to produce as a long wire.

A method of producing such an oxide superconducting wire incorporating a Bi-2223-based oxide superconductor has been disclosed, for example, in Patent literature 1. The disclosed production method is conducted as follows. First, a material power having a Bi-2223-based oxide superconductor is filled into a silver tube. The silver tube filled with the material powder is processed by drawing to form a single-filament superconducting wire. Next, a plurality of single-filament superconducting wires are housed in a silver tube to form a multifilament superconducting wire. The multifilament superconducting wire is subjected to a twisting process. The twisted wire is processed by rolling. Then, the rolled wire is heat-treated to complete the production of a tape-shaped oxide superconducting wire having a width of 3.0 mm and a thickness of 0.22 mm (see paragraphs [0045] to [0047] of Patent literature 1).
Patent literature 1: the published Japanese patent application Tokukaihei 7-105753.

### DISCLOSURE OF THE INVENTION

### Problem to be Solved by the Invention

When an oxide superconducting wire is used, for example, for an AC superconducting cable, a superconducting magnet, and a product incorporating the superconducting magnet, it becomes important to increase the wire's critical current density and to decrease the wire's AC loss.

In the fundamental formula based on the Bean model, however, the AC loss is proportional to the product of the critical current density, the thickness of the oxide superconducting wire, and the intensity of the applied magnetic field. Consequently, it has been extremely difficult to decrease the AC loss when the critical current density is increased.

In view of the above circumstance, an object of the present invention is to offer the following products and method:
(a) an oxide superconducting wire that can not only increase its critical current density but also decrease its AC loss,
(b) a superconducting structure,
(c) a method of producing an oxide superconducting wire,
(d) a superconducting cable and a superconducting magnet each of which incorporates the oxide superconducting wire, the superconducting structure, or an oxide superconducting wire produced by the method of producing an oxide superconducting wire, and
(e) a product incorporating the superconducting magnet.

### Means to Solve the Problem

The present invention offers an oxide superconducting wire that has the shape of a tape and that is formed by embedding in a matrix a plurality of filaments, each of which has a Bi-2223-based oxide superconductor. The oxide superconducting wire has a cross-sectional area of at most 0.5 mm² in a cross section perpendicular to the direction of its length. In the cross section of the oxide superconducting wire, the filaments have an average cross-sectional area per filament of at least 0.2% and at most 6% of the cross-sectional area of the oxide superconducting wire.

In the oxide superconducting wire of the present invention, it is desirable that the filaments have an average aspect ratio of more than 10.

In the oxide superconducting wire of the present invention, it is desirable that the filaments turn around the longitudinal center axis of the oxide superconducting wire at a twisting pitch of at most 8 mm, more desirably at most 5 mm. In the above description, the twisting pitch is the pitch at which the filaments turn.

In the oxide superconducting wire of the present invention, it is desirable that a barrier layer be formed between the filaments.

In the oxide superconducting wire of the present invention, it is desirable that a metal tape be provided on a surface of the matrix.

In the oxide superconducting wire of the present invention, it is desirable that an insulating film be provided on the surface of the matrix.

In the oxide superconducting wire of the present invention, it is desirable that a metal tape be provided on a surface of the matrix and that an insulating film be provided on the surface of the metal tape.

The present invention also offers a superconducting structure formed by twisting together a plurality of oxide superconducting wires described above. In the superconducting structure, the together-twisted oxide superconducting wires include at least one oxide superconducting wire that is bent edgewise.

The present invention also offers another superconducting structure that has:
(a) a plurality of oxide superconducting wires described above,
(b) a tape-shaped protective film which has two opposing main faces and in which the multiple oxide superconducting wires are placed, and
(c) a metal tape that is provided on each of the opposing main faces.

In the superconducting structure described immediately above, it is desirable that a high-resistivity body that has a resistivity higher than that of the protective film is placed between the neighboring oxide superconducting wires.

The present invention also offers yet another superconducting structure that has:
(a) a plurality of oxide superconducting wires described above and
(b) a tape-shaped insulating protective film in which the multiple oxide superconducting wires are placed.

The present invention also offers a method of producing an oxide superconducting wire. The method has the following steps:
(a) a step of filling a first metal sheath with a material powder including both a powder of an oxide superconductor and a powder of a nonsuperconductor,
(b) a step of processing the first metal sheath filled with the material powder by drawing to form a single-filament superconducting wire,
(c) a step of housing a plurality of single-filament superconducting wires described above into a second metal sheath,
(d) a step of processing the second metal sheath that houses the single-filament superconducting wires by drawing to form a multifilament superconducting wire,
(e) a step of processing the multifilament superconducting wire by rolling, and
(f) a step of heat-treating the rolled multifilament superconducting wire.

### In the Method Described Above:

(g) in the material powder, the number of particles in a powder of a nonsuperconductor having a particle diameter of at most 2 μm constitutes at least 95% of the total number of particles in the powder of the nonsuperconductor,
(h) the cross-sectional areas of the single-filament superconducting wires in the multifilament superconducting wire before being processed by rolling have a coefficient of variation (COV) of at most 15%,
(i) the step of processing the multifilament superconducting wire by rolling is performed at a rolling reduction of at most 82%, and
(j) the step of heat-treating the rolled multifilament superconducting wire is performed under a pressure of at least 200 atmospheres.

In the method of the present invention for producing an oxide superconducting wire, it is desirable that the method further include a step of twisting the multifilament superconducting wire before the step of processing the multifilament superconducting wire by rolling, the step of twisting being performed a plurality of times.

In the method of the present invention for producing an oxide superconducting wire, it is desirable that the method further include a step of forming a barrier layer in the oxide superconducting wire.

The present invention also offers a superconducting cable that incorporates a member selected from the group consisting of the following members:
(a) any of the above-described oxide superconducting wires,
(b) any of the above-described superconducting structures, and
(c) an oxide superconducting wire produced by any of the above-described methods of producing an oxide superconducting wire.

The present invention also offers a superconducting magnet that incorporates a member selected from the group consisting of the following members:
(a) any of the above-described oxide superconducting wires,
(b) any of the above-described superconducting structures, and
(c) an oxide superconducting wire produced by any of the above-described methods of producing an oxide superconducting wire.

The present invention also offers a motor armature incorporating the above-described superconducting magnet.

The present invention also offers a refrigerator-cooled-type magnet system incorporating the above-described superconducting magnet.

The present invention also offers an MRI (a magnetic resonance imager) incorporating the above-described superconducting magnet.

### EFFECT OF THE INVENTION

The present invention can offer the following products and method:
(a) an oxide superconducting wire that can not only increase its critical current density but also decrease its AC loss,
(b) a superconducting structure,
(c) a method of producing an oxide superconducting wire that can produce an oxide superconducting wire as described above,
(d) a superconducting cable and a superconducting magnet each of which incorporates the oxide superconducting wire, the superconducting structure, or an oxide superconducting wire produced by the method of producing an oxide superconducting wire, and
(e) a product incorporating the superconducting magnet.

### BRIEF DESCRIPTION OF THE DRAWING

FIG. 1 is a perspective view showing a part of a desirable example of the oxide superconducting wire of the present invention.

FIG. 2 is a diagram schematically showing the cross section along the line II-II perpendicular to the direction of the length of the oxide superconducting wire shown in FIG. 1.

FIG. 3 is a perspective view showing the interior of a part of another desirable example of the oxide superconducting wire of the present invention.

FIG. 4 is a schematic cross-sectional view of yet another desirable example of the oxide superconducting wire of the present invention.

FIG. 5 is a schematic cross-sectional view of yet another desirable example of the oxide superconducting wire of the present invention.

FIG. 6 is a schematic cross-sectional view of yet another desirable example of the oxide superconducting wire of the present invention.

FIG. 7 is a schematic cross-sectional view of yet another desirable example of the oxide superconducting wire of the present invention.

FIG. 8 is a schematic cross-sectional view of yet another desirable example of the oxide superconducting wire of the present invention.

FIG. 9 is a schematic cross-sectional view of a desirable example of the superconducting structure of the present invention.

FIG. 10 is a schematic cross-sectional view of another desirable example of the superconducting structure of the present invention.

FIG. 11 is a schematic cross-sectional view of yet another desirable example of the superconducting structure of the present invention.

FIG. 12 is a flowchart for a desirable example of the method of the present invention for producing an oxide superconducting wire.

FIG. 13 is a schematic diagram for illustrating a part of the production process for the method of the present invention for producing an oxide superconducting wire.

FIG. 14 is a schematic diagram for illustrating another part of the production process for the method of the present invention for producing an oxide superconducting wire.

FIG. 15 is a schematic diagram for illustrating yet another part of the production process for the method of the present invention for producing an oxide superconducting wire.

FIG. 16 is a schematic diagram for illustrating yet another part of the production process for the method of the present invention for producing an oxide superconducting wire.

FIG. 17 is a schematic diagram for illustrating yet another part of the production process for the method of the present invention for producing an oxide superconducting wire.

FIG. 18 is a schematic diagram for illustrating the rolling reduction in the method of the present invention for producing an oxide superconducting wire.

FIG. 19 is a flowchart for a desirable example of a step in which the twisting operation of the multifilament superconducting wire before being processed by rolling is performed a plurality of times, in the method of the present invention for producing an oxide superconducting wire.

FIG. 20 is a schematic diagram illustrating the transposition of an oxide superconducting wire.

FIG. 21 is a schematic plan view illustrating a state in which an oxide superconducting wire is bent edgewise.

### EXPLANATION OF THE SIGN

1: Oxide superconducting wire
2: Matrix
3: Filament
4: Barrier layer
5: First metal sheath
6: Material powder
7: Single-filament superconducting wire
8: Second metal sheath
9: Multifilament superconducting wire
10 and 12: Metal tape
11: Insulating film
13: Protective film
13a and 16a: Main face
14: Superconducting structure
15: High-resistivity body
16: Insulating protective film

### BEST MODE FOR CARRYING OUT THE INVENTION

Embodiments of the present invention are explained below. In the drawing showing the present invention, the same reference sign represents the same component or an equivalent thereof.

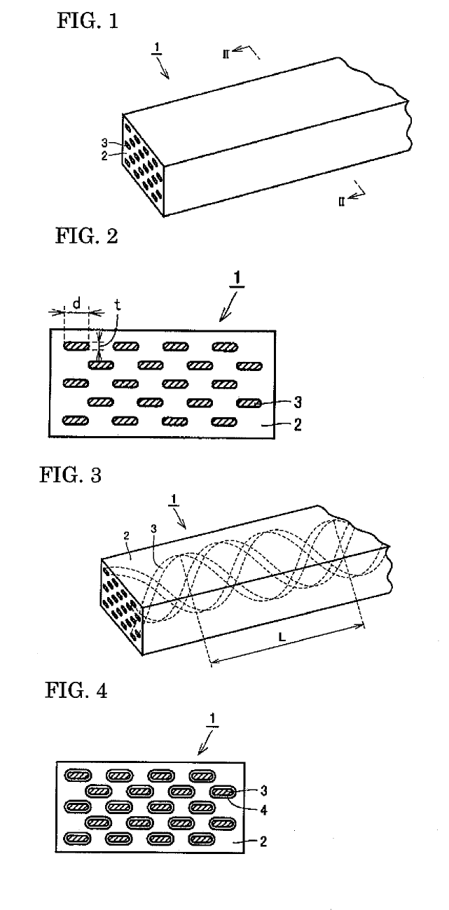

FIG. 1 is a perspective view showing a part of a desirable example of the oxide superconducting wire of the present invention. FIG. 2 schematically shows the cross section along the line II-II perpendicular to the direction of the length of the oxide superconducting wire shown in FIG. 1. An oxide superconducting wire 1 of the present invention is formed in the shape of a tape and is provided with a matrix 2 and filaments 3, which are embedded in the matrix 2 and each of which has a Bi-2223-based oxide superconductor. The filaments 3 are housed in a metal sheath and have a structure in which each filament 3 has the Bi-2223-based oxide superconductor.

The Present Invention has the Following Features:
(a) the cross section perpendicular to the direction of the length of the oxide superconducting wire 1 shown in FIG. 2 has a cross-sectional area of at most 0.5 mm², and
(b) in the cross section of the oxide superconducting wire 1, the filaments 3 have an average cross-sectional area per filament of at least 0.2% and at most 6%, desirably at least 2% and at most 6%, of the cross-sectional area of the oxide superconducting wire 1.

The present inventor conceived based on the fundamental formula for the above-described Bean model that even when the critical current density was increased, the AC loss could be decreased by minimizing the cross-sectional area of the oxide superconducting wire 1 with a minimum of decrease in the number of filaments 3. The present inventor studied diligently based on the above conception. Through this study, the present inventor has found that an oxide superconducting wire can not only increase its critical current density but also decrease its AC loss when the following conditions are met:
(a) the cross section perpendicular to the direction of the length of the oxide superconducting wire 1 has a cross-sectional area of at most 0.5 mm²,
(b) a Bi-2223-based oxide superconductor is used as the superconductor that constitutes each of the filaments 3, and
(c) the filaments 3 have an average cross-sectional area per filament of at least 0.2% and at most 6%, desirably at least 2% and at most 6%, of the cross-sectional area of the oxide superconducting wire 1.

Thus, the present invention is completed.

The average cross-sectional area per filament of the filaments 3 in the cross section perpendicular to the direction of the length of the oxide superconducting wire 1 can be obtained by the following method. First, a calculation is made to obtain the sum of the cross-sectional areas of the multiple filaments 3 existing in the cross section perpendicular to the direction of the length of the oxide superconducting wire 1. Then, the sum is divided by the number of filaments 3.

In the present invention, the Bi-2223-based oxide superconductor is a superconductor expressed by the composition formula Bi_{α}Pb_{β}Sr_{γ}Ca_{δ}Cu_{ε}Oₓ (where 1.75≦α≦2 .1, 0≦β0 .4, 1.7≦γ≦2 .1, 1.7≦δ≦2.2, ε=3.0, 9.8≦x≦10.2). In the above formula, Bi stands for bismuth, Pb lead, Sr strontium, Ca calcium, Cu copper, and O oxygen. In addition, α denotes the composition ratio of bismuth, β the composition ratio of lead, γ the composition ratio of strontium, δ the composition ratio of calcium, ε the composition ratio of copper, and x the composition ratio of oxygen. The matrix 2 is formed by using, for example, silver as its material.

In the oxide superconducting wire 1 of the present invention, it is desirable that the filaments 3 have an average aspect ratio of more than 10. When the filaments 3 have an average aspect ratio of more than 10, the oxide superconducting wire 1 of the present invention tends to further increase its critical current density. The average aspect ratio of the filaments 3 is defined as the average value of the ratios of the width to the thickness of the multiple filaments 3 existing in the cross section perpendicular to the direction of the length of the oxide superconducting wire 1. For example, by referring to FIG. 2, the aspect ratio of one of the filaments 3 can be obtained by using the formula (the width “d” of a filament 3)/(the thickness “t” of that filament 3). The aspect ratio expressed by the foregoing formula is calculated on each of the multiple filaments 3 existing in the cross section perpendicular to the direction of the length of the oxide superconducting wire 1. The calculated results are summed. The sum is divided by the number of filaments 3. Thus, the average aspect ratio of the filaments 3 is obtained.

In the oxide superconducting wire 1 of the present invention, as shown, for example, in FIG. 3, which is a perspective view showing the interior, it is desirable that the filaments 3 be embedded in the matrix 2 in a twisted state. In this state, the filaments 3 turn around the longitudinal center axis of the oxide superconducting wire 1. This state produces a tendency to enable a further decrease in the AC loss. The longitudinal center axis of the oxide superconducting wire 1 is the axis passing through the center of the cross section perpendicular to the direction of the length of the oxide superconducting wire 1. The center axis extends along the direction of the length of the oxide superconducting wire 1. The filaments 3 can be brought into the twisted state (the state in which the filaments 3 turn around the longitudinal center axis of the oxide superconducting wire 1) through the following process. First, a multifilament superconducting wire before being processed by the below-described rolling operation is twisted by a conventional, well-known method. Then, the twisted multifilament superconducting wire is subjected to a rolling process and a heat treatment. Thus, the above-described oxide superconducting wire 1 is obtained.

As the twisting pitch, which is the pitch at which the filaments 3 turn, is decreased, the AC loss increases a tendency to be decreased. In view of the decreasing of the AC loss, it is desirable that the filaments 3 have a twisting pitch of at most 8 mm. In view of both the further increasing of the critical current density and the further decreasing of the AC loss, it is desirable that the twisting pitch be at most 5 mm. The twisting pitch of the filaments 3 is indicated by the length “L” shown in FIG. 3. Conventional filaments have a large cross-sectional area in the cross section perpendicular to the direction of the length of the oxide superconducting wire. Consequently, it has been difficult to achieve a twisting pitch larger than 8 mm due to a problem in processing. On the other hand, in the present invention, the cross-sectional area in the cross section perpendicular to the direction of the length of the oxide superconducting wire 1 is as extremely small as no more than 0.5 mm². Therefore, it becomes possible to achieve a twisting pitch of at most 8 mm, desirably at most 5 mm.

In the oxide superconducting wire 1 of the present invention, as shown, for example, in schematic cross-sectional views in FIGS. 4 and 5, it is desirable to form a barrier layer 4 between the neighboring filaments 3. When this structure is employed, the AC loss tends to be decreased. In particular, when the filaments 3 are twisted, the tendency is further increased. The barrier layer 4 is formed by using a material having an electric resistivity at least 10 times that of silver at room temperature (25° C.). The material can be, for example, strontium carbonate, copper oxide, zirconia, or a Bi-2201 oxide superconductor.

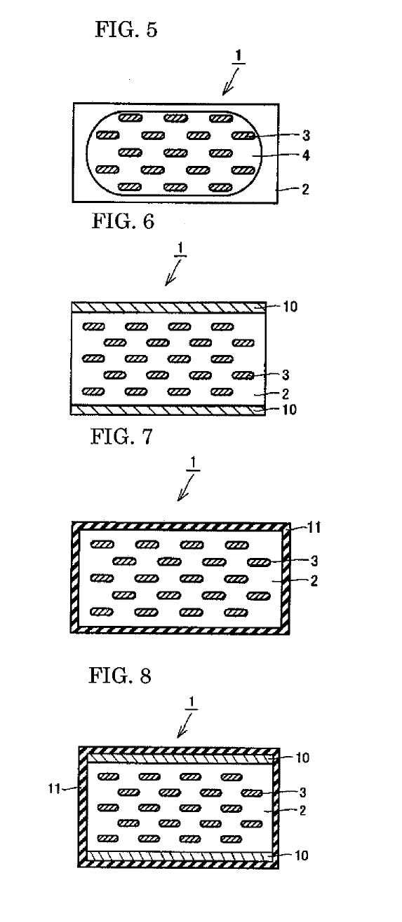

In the oxide superconducting wire 1 of the present invention, as shown, for example, in a schematic cross-sectional view in FIG. 6, it is desirable to provide a metal tape 10 on a surface of the matrix 2. When this structure is employed, because the oxide superconducting wire 1 of the present invention is reinforced by the metal tape 10, this structure gives a tendency to facilitate the production of a coil winding and a superconducting cable both incorporating the oxide superconducting wire 1 of the present invention. The metal tape 10 can be placed on a surface of the matrix 2 by bonding a tape made of metal such as copper or stainless steel to a surface of the matrix 2 using solder or the like.

In the oxide superconducting wire 1 of the present invention, as shown, for example, in a schematic cross-sectional view in FIG. 7, it is desirable to provide an insulating film 11 on the surface of the matrix 2. When this structure is employed, because the surface of the oxide superconducting wire 1 of the present invention is insulated in advance, this structure gives a tendency to facilitate the production of a coil winding incorporating the oxide superconducting wire 1 of the present invention. The insulating film 11 can be placed on the surface of the matrix 2 by lapping a tape made of resin such as polyimide on the surface of the matrix 2 using a half-lapping method (in this method, the tape is lapped by overlapping with the previously lapped tape by half the width of the tape). Alternatively, for example, the insulating film 11 can also be placed on the surface of the matrix 2 by the following method. First, two tapes which are made of resin such as polyimide and each of which has a width larger than that of the oxide superconducting wire 1 of the present invention are prepared. Then, the two tapes are not only bonded to the corresponding surfaces of the matrix 2, respectively, along the length of the oxide superconducting wire 1 but also bonded with each other.

In the oxide superconducting wire 1 of the present invention, as shown, for example, in a schematic cross-sectional view in FIG. 8, it is desirable not only to provide a metal tape 10 on a surface of the matrix 2 but also to provide an insulating film 11 on the surface of the metal tape 10. When this structure is employed, because both the insulating film 11 secures the insulating performance and the metal tape 10 acts as the reinforcement, this structure gives a tendency to enable the application to a superconducting magnet, which is subjected to a large force at the time of the operation, and to a high-current-carrying-capacity superconducting cable, which is subjected to a large load at the time of the installation. The metal tape 10 can be placed on a surface of the matrix 2 by bonding a tape made of metal such as copper or stainless steel to a surface of the matrix 2 using solder or the like. The insulating film 11 can be placed on the surface of the metal tape 10 by bonding a tape made of resin such as polyimide to the surface of the metal tape 10.

A superconducting structure can be produced by the following method. First, at least one oxide superconducting wire 1 covered with the insulating film 11 shown in FIG. 7 or 8 described above is bent edgewise. Then, a plurality of oxide superconducting wires 1 including the at least one oxide superconducting wire 1 bent edgewise are twisted together. The superconducting structure having the foregoing configuration can be produced to have low loss, high current-carrying capacity, and small size. Consequently, the use of the superconducting structure having the foregoing configuration gives a tendency to enable the production of a high-capacity AC apparatus, such as a superconducting cable or a superconducting magnet. In the present invention, the expression “to be bent edgewise” is used to mean the following bending operation. As shown, for example, in FIG. 21, of the multiple oxide superconducting wires 1, an oxide superconducting wire 1 positioned at the inside is bent so that at least one part thereof can be positioned at the outside, and an oxide superconducting wire 1 positioned at the outside is bent so that at least one part thereof can be positioned at the inside. The superconducting structure having the foregoing configuration can be produced, for example, by twisting together three oxide superconducting wires 1 each covered with the insulating film 11 while they are being continuously bent edgewise at a bending diameter of 1,000 mm.

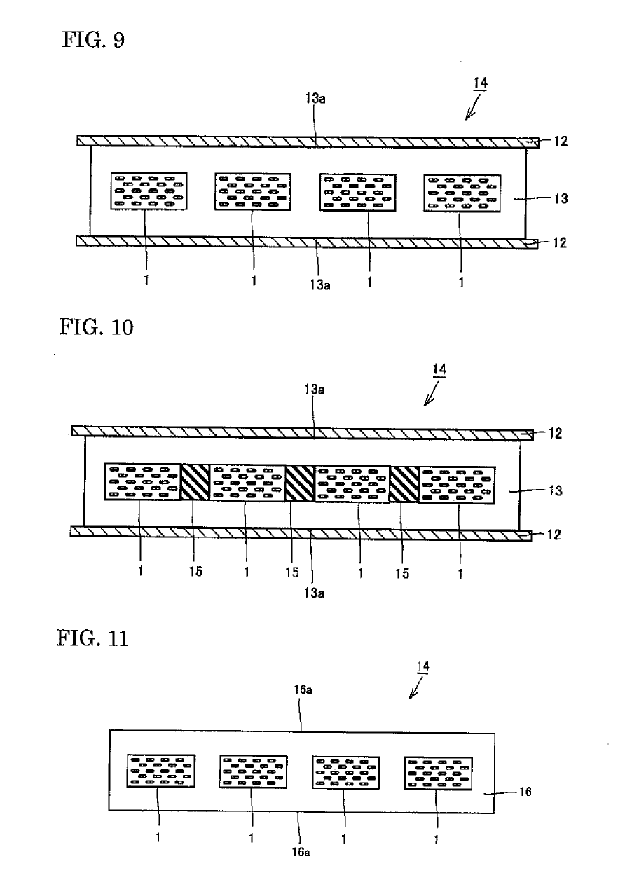

As shown, for example, in a schematic cross-sectional view in FIG. 9, a superconducting structure 14 can also be produced by the following method. First, a plurality of oxide superconducting wires 1 described above are placed in a tape-shaped protective film 13. Then, a metal tape 12 is placed on each of the opposing main faces 13a of the protective film 13. The superconducting structure 14 having the foregoing configuration can decrease the AC loss in the magnetic field perpendicular to the main faces 13a of the protective film 13. As a result, this configuration gives a tendency to increase the current-carrying capacity per oxide superconducting wire 1. The superconducting structure 14 having the foregoing configuration can be suitably used for an AC apparatus that is required to have low AC loss and high capacity. The protective film 13 can be formed, for example, by using solder or another alloy.

In the superconducting structure 14 shown in FIG. 9, as shown, for example, in a schematic cross-sectional view in FIG. 10, it is desirable to place a high-resistivity body 15 that has a resistivity higher than that of the protective film 13 between the neighboring oxide superconducting wires 1. The employment of this configuration gives a tendency not only to further decrease the AC loss in the magnetic field perpendicular to the main faces 13a of the protective film 13 but also to further increase the current-carrying capacity per oxide superconducting wire 1.

As shown, for example, in a schematic cross-sectional view in FIG. 11, a superconducting structure 14 can also be produced by placing a plurality of oxide superconducting wires 1 described above in an insulating protective film 16 made of polyester or the like having the shape of a tape. The superconducting structure 14 having the foregoing configuration gives a tendency to enable the decreasing of the AC loss in the magnetic field perpendicular to the main faces 16a of the insulating protective film 16. Because the superconducting structure 14 having the foregoing configuration has flexibility, its handling tends to become easy. The insulating protective film 16 can be formed by using not only polyester but also, for example, polypropylene, polyethylene, polytetrafluoroethylene, or polyimide.

In the oxide superconducting wire 1 of the present invention, it is desirable that the Bi-2223-based oxide superconductor in the filament 3 have a relative density of at least 99%. When this condition is satisfied, the critical current density tends to further increase. In the present invention, the relative density (%) can be obtained using the formula 100×(total volume of the oxide superconductor ˜total volume of the void)/(total volume of the oxide superconductor). In the present invention, the critical current density can be obtained using the formula (value of the critical current of the oxide superconducting wire 1)/(cross-sectional area in the cross section perpendicular to the direction of the length of the oxide superconducting wire 1).

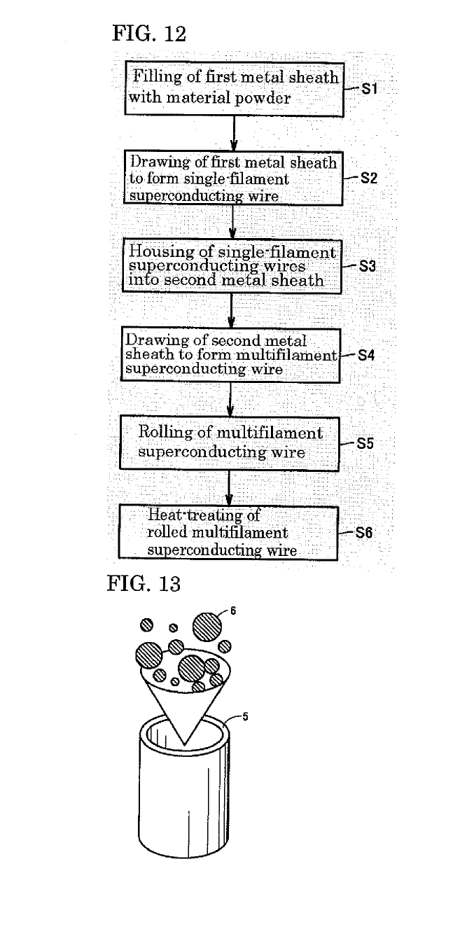

Next, the method of the present invention for producing an oxide superconducting wire is explained below. FIG. 12 shows a flowchart for a desirable example of the method of the present invention for producing an oxide superconducting wire.

By referring to FIG. 12, first, in Step S1, as shown, for example, in a schematic perspective view in FIG. 13, a first metal sheath 5 is filled with a material powder 6 including both a powder of an oxide superconductor and a powder of a nonsuperconductor. In the present invention, in the material powder 6, the number of particles in a powder of a nonsuperconductor having a particle diameter of at most 2 μm constitutes at least 95% of the total number of particles in the powder of the nonsuperconductor. The powder of the nonsuperconductor is a powder of a material having an electric resistivity higher than that of the oxide superconductor at the critical temperature of the oxide superconductor. The types of the material for the powder of the nonsuperconductor include (Ca, Sr)₂CuO₃, (Ca, Sr)₂ PbO₄, and (Ca, Sr)₁₄Cu₂₄O₃. The types of the material for the powder of the oxide superconductor to be used in the method of the present invention for producing an oxide superconducting wire include the above-described Bi-2223-based oxide superconductor.

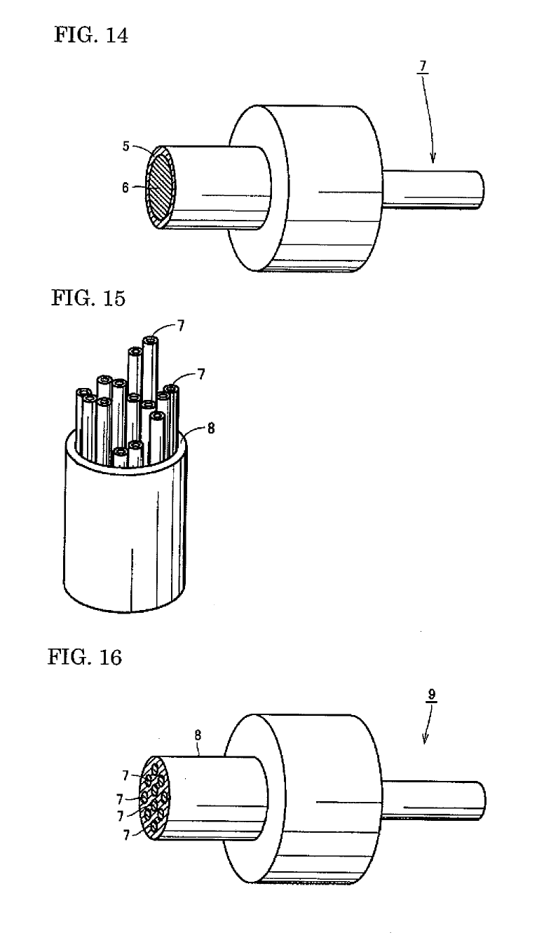

In Step S2, as shown, for example, in a schematic perspective view in FIG. 14, the first metal sheath 5 filled with the material powder 6 is processed by drawing to form a single-filament superconducting wire 7.

In Step S3, as shown, for example, in a schematic perspective view in FIG. 15, a plurality of single-filament superconducting wires 7 are housed in a second metal sheath 8.

In Step S4, as shown, for example, in a schematic perspective view in FIG. 16, the second metal sheath 8 that houses the single-filament superconducting wires 7 is processed by drawing to form a multifilament superconducting wire 9. In the present invention, the coefficient of variation (COV) in the cross-sectional areas of the single-filament superconducting wires in the multifilament superconducting wire before being processed by rolling is at most 15%. The coefficient of variation (COV) described above is the value obtained by dividing the standard deviation of the cross-sectional areas of the multiple single-filament superconducting wires in the cross section perpendicular to the direction of the length of the multifilament superconducting wire before being processed by rolling with the average value of the foregoing cross-sectional areas of the multiple single-filament superconducting wires.

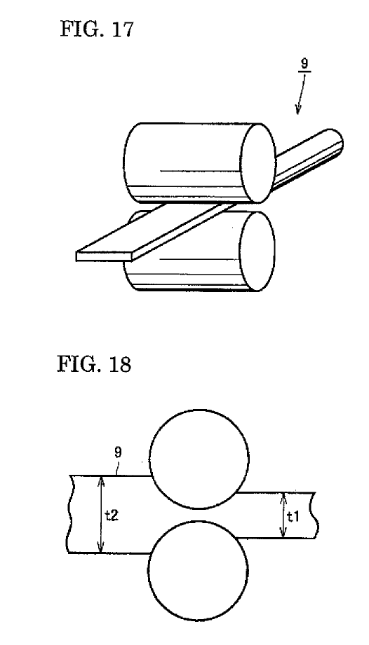

In Step S5, as shown, for example, in a schematic perspective view in FIG. 17, the multifilament superconducting wire 9 is processed by rolling to obtain the shape of a tape. In the present invention, the rolling reduction in the rolling process is at most 82%. By referring to, for example, a schematic side view in FIG. 18, the rolling reduction (%) is defined as the percentage of the decrease in the thickness “t1” of the multifilament superconducting wire 9 after being processed by the rolling over the thickness “t2” of the multifilament superconducting wire 9 before being processed by the rolling (the percentage is expressed as 100×{1−(t1/t2)}).

In Step S6, the rolled multifilament superconducting wire 9 is heat-treated to complete the production of the tape-shaped oxide superconductor. In the present invention, the heat treatment is performed under a pressure of at least 200 atmospheres.

The present inventor studied to decrease the cross-sectional area in the cross section perpendicular to the direction of the length of the oxide superconducting wire with an intention to maintain the critical current density of the oxide superconducting wire unchanged. The present inventor, however, has found that when the foregoing cross-sectional area is decreased, the critical current density is also decreased.

The present inventor has also found that the decrease in the critical current density is caused by the fact that when the foregoing cross-sectional area is decreased, the degree of processing by drawing is increased, so that the COV increases, thereby impeding the current flow in the oxide superconducting wire.

The present inventor further studied the relation between the increase in the degree of processing and the magnitude of the COV. The study has revealed that when the cross-sectional area of the oxide superconducting wire is decreased, a lump of a nonsuperconductor having a diameter of at most 2 μm becomes a starting point to hinder the uniform change in the shape of the single-filament superconducting wire. The study has also revealed that the diameter of the particle of the nonsuperconductor maintains almost the same value from the time of the filling into the first metal sheath to the completion of the rolling process.

Based on the above-described findings, the present inventor conducted a further study intensely. The study has revealed that when the number of particles in a powder of a nonsuperconductor having a particle diameter of at most 2 μm constitutes at least 95% of the total number of particles in the powder of the nonsuperconductor, the COV becomes at most 15%, enabling the decrease in the cross-sectional area of the oxide superconducting wire.

The oxide superconducting wire whose cross-sectional area was decreased through the above-described method, however, developed variations in critical current density. Accordingly, the present inventor examined the oxide superconducting wire having low critical current density. The examination has revealed that the wire has a large number of pinholes formed on its surface and that in the pinhole-formed portion, the oxide superconductor constituting the filament has a low relative density. A further detailed examination has shown a possibility that there is a correlation between the rolling reduction at the time of the rolling of the multifilament superconducting wire and the number of pinholes.

Subsequently, the present inventor conducted an experiment in which the foregoing rolling reduction was varied in a range of 70% to 85% and the rolled multifilament superconducting wire was heat-treated under a pressure of at least 200 atmospheres to increase the relative density of the oxide superconductor constituting the filament in the oxide superconducting wire. The result has confirmed that the oxide superconducting wire obtained through the following procedure has both a cross-sectional area of at most 0.5 mm² in the cross section perpendicular to the direction of its length and a high critical current density:
(a) a material powder in which the number of particles in a powder of a nonsuperconductor having a particle diameter of at most 2 μm constitutes at least 95% of the total number of particles in the powder of the nonsuperconductor is used to achieve that the coefficient of variation (COV) in the cross-sectional areas of the single-filament superconducting wires in the multifilament superconducting wire before being processed by rolling becomes at most 15%,
(b) the rolling operation is performed at a rolling reduction of at most 82%, and
(c) the rolled multifilament superconducting wire is heat-treated under a pressure of at least 200 atmospheres.

In addition, in view of the achieving of an oxide superconducting wire that has not only a further increased critical current density but also a further decreased AC loss, it is desirable that in the cross section of the oxide superconducting wire produced by the method of the present invention for producing an oxide superconducting wire, the filaments have an average cross-sectional area per filament of at least 0.2% and at most 6%, more desirably at least 2% and at most 6%, of the cross-sectional area of the oxide superconducting wire.

In the method of the present invention for producing an oxide superconducting wire, it is desirable to perform a plurality of times the step of twisting the multifilament superconducting wire before being processed by rolling.

When this method is employed, the twisting pitch of the filaments included in the oxide superconducting wire can be further decreased. When the twisting pitch is decreased to at most 8 mm, more desirably at most 5 mm, the AC loss can have a tendency to be further decreased, as described above.

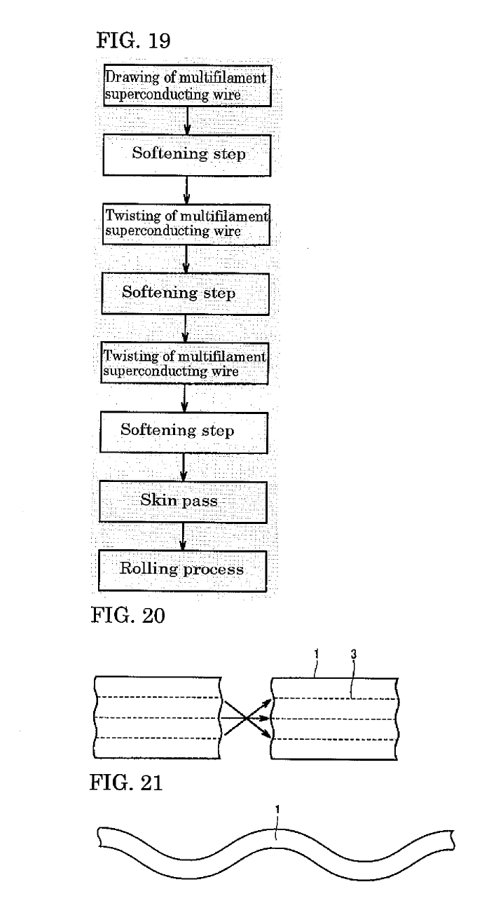

FIG. 19 shows a desirable example of a flowchart for a process in which the twisting operation of the multifilament superconducting wire before being processed by rolling is performed a plurality of times. As shown in the flowchart, first, the multifilament superconducting wire before being processed by rolling is processed by drawing. Then, the drawn multifilament superconducting wire is subjected to a softening step and subsequently is twisted. Then, again, it is subjected to a softening step and subsequently is twisted. Then, again, it is subjected to a softening step. Subsequently, after it is subjected to a step of skin pass, it is processed by rolling. In the above description, the softening step is performed, for example, by maintaining the multifilament superconducting wire for at least 0.5 hours under the atmosphere at a temperature of at least 200° C. and at most 300° C. The step of skin pass is a step for smoothing the surface of the multifilament superconducting wire, for example, by passing it through a die.

In the method of the present invention for producing an oxide superconducting wire, it is desirable to form a barrier layer in the oxide superconducting wire. When the barrier layer is formed, the AC loss tends to decrease. In particular, when the filaments are twisted, this tendency is further increased. The barrier layer can be formed between the filaments and the matrix both constituting the oxide superconducting wire, for example, by producing the oxide superconducting wire using single-filament superconducting wires each coated with material for forming the barrier layer. In the present Description, the term “single-filament superconducting wire” is used before the above-described heat treatment is performed, and the term “filament” is used after the heat treatment is performed.

In the oxide superconducting wire obtained through the method of the present invention for producing an oxide superconducting wire, it is desirable that the oxide superconductor in the filament have a relative density of at least 99%. When this condition is satisfied, the critical current density tends to be further increased.

Both of the oxide superconducting wire 1 of the present invention and the oxide superconducting wire produced by the method of the present invention for producing an oxide superconducting wire have a small cross-sectional area in the cross section perpendicular to the direction of the length of them. Consequently, they enable a compact transposition. The term “transposition” is used to mean that, for example, as shown in a schematic diagram in FIG. 20, the outside and inside of the oxide superconducting wire 1 are reversed as a measure for preventing the nonuniform current flow when AC current flows. The transposition can be performed by bending the oxide superconducting wire 1 edgewise, as shown in a schematic diagram in FIG. 21, for example.

The conventional oxide superconducting wire has a large cross-sectional area in the cross section perpendicular to the direction of its length. Consequently, to maintain the critical current density, the wire can only be bent edgewise at a bending diameter of about 1,000 mm. On the other hand, both of the oxide superconducting wire of the present invention and the oxide superconducting wire produced by the method of the present invention for producing an oxide superconducting wire have a small cross-sectional area in the cross section perpendicular to the direction of the length of them. Consequently, they can be bent edgewise at a bending diameter of about 500 mm. As a result, a more compact transposition becomes possible.

All of the oxide superconducting wire 1 of the present invention, the superconducting structure 14 of the present invention incorporating the oxide superconducting wire 1, and the oxide superconducting wire produced by the method of the present invention for producing an oxide superconducting wire have a small cross-sectional area in the cross section perpendicular to the direction of the length of them. Consequently, when they are used for a superconducting cable, a superconducting magnet, or another apparatus, the apparatus can have a small size and a light weight.

A superconducting magnet incorporating the oxide superconducting wire of the present invention, the superconducting structure of the present invention incorporating the foregoing oxide superconducting wire, or the oxide superconducting wire produced by the method of the present invention for producing an oxide superconducting wire can be used for a product such as a motor armature, a refrigerator-cooled-type magnet system, or an MRI.

The oxide superconducting wire and superconducting structure both of the present invention can decrease the AC loss. Consequently, both a superconducting magnet incorporating either of them and an apparatus, such as a motor armature, a refrigerator-cooled-type magnet system, or an MRI, incorporating the foregoing superconducting magnet tend to be able to decrease the load when they are cooled.

The oxide superconducting wire and superconducting structure both of the present invention can be formed with the shape of a thin tape having a small cross-sectional area. Consequently, in a superconducting cable incorporating either of them, the strain produced in them when they are wound on the core member tends to be decreased and the magnitude of the critical current tends not to decrease.

### EXAMPLE

### Example 1

Bi₂O₃, PbO, SrCO₃, CaCO₃, and CuO were used. Powders of them were mixed to achieve the composition ratio Bi:Pb:Sr:Ca:Cu=1.79:0.4:1.96:2.18:3. The mixed powder was treated by heating and pulverization to obtain a material powder having a powder of a Bi-2223-based oxide superconductor. The material powder was filled into a silver tube having an outer diameter of 12 mm and an inner diameter of 10 mm, which was used as the first metal sheath.

The silver tube filled with the powder was processed by drawing until the diameter became 2 mm to produce a single-filament superconducting wire. A barrier layer made of strontium carbonate was formed on the surface of the single-filament superconducting wire. Ninety-one single-filament superconducting wires each having the barrier layer on the surface were housed in a silver tube having an outer diameter of 36 mm and an inner diameter of 27 mm, which was used as the second metal sheath. The silver tube that housed the single-filament superconducting wires was processed by drawing until the diameter became 0.9 mm to produce a multifilament superconducting wire.

The multifilament superconducting wire was subjected to a softening step in which the wire was maintained for one hour in an atmosphere at 250° C. and a subsequent step for twisting the wire. The combination of the steps was repeated until the filaments in the oxide superconducting wire to be obtained in this example had a twisting pitch of 8 mm. The multifilament superconducting wire was further subjected to a softening step in which the wire was maintained for one hour in an atmosphere at 250° C. Then, the wire underwent a step of skin pass and a subsequent step of rolling process.

The rolled multifilament superconducting wire was subjected to the first sintering process in the atmosphere. Then, the wire was rolled again. Subsequently, the wire was heat-treated for 50 hours at 850° C. under a pressure of 200 atmospheres. Thus, a tape-shaped oxide superconducting wire (the oxide superconducting wire in Example 1) was obtained.

A part of the oxide superconducting wire in Example 1 was cut in a direction perpendicular to the direction of its length. The cut section showed a structure in which the filaments were embedded in the matrix made of silver and each filament was surrounded by the barrier layer.

A measurement made on the section showed that the cross-sectional area was 0.5 mm². In the section, the average cross-sectional area per filament was 0.2% of the cross-sectional area of the entire oxide superconducting wire. The filaments included in the oxide superconducting wire in Example 1 had an average aspect ratio of more than 10.

The thus obtained oxide superconducting wire in Example 1 was subjected to a measurement of critical current density under a condition of 77 K (kelvin) and 0 T (tesla). The measured result is shown in Table I. As shown in Table I, it was confirmed that the oxide superconducting wire in Example 1 has a critical current density of 11 kA/cm².

The oxide superconducting wire in Example 1 was also subjected to a measurement of AC loss. The measured result is shown in Table I. As shown in Table I, it was confirmed that the oxide superconducting wire in Example 1 has an AC loss of 15 μJ/A/m/cycle.

### Example 2

An oxide superconducting wire in Example 2 was produced using the same method and same condition as those used in Example 1, except that 37 single-filament superconducting wires each having a diameter of 3.8 mm were housed in the second metal sheath so that the average cross-sectional area per filament could be adjusted to 1% of the cross-sectional area of the entire oxide superconducting wire.

A part of the oxide superconducting wire in Example 2 was cut in a direction perpendicular to the direction of its length. The cut section showed a structure in which the filaments were embedded in the matrix made of silver and each filament was surrounded by the barrier layer.

A measurement made on the section showed that the cross-sectional area was 0.5 mm². The filaments included in the oxide superconducting wire in Example 2 had an average aspect ratio of more than 10.

The oxide superconducting wire in Example 2 was subjected to measurements of critical current density and AC loss using the same method and same condition as those used in Example 1. The measured results are shown in Table I. As shown in Table I, the oxide superconducting wire in Example 2 has a critical current density of 12 kA/cm² and an AC loss of 14 μJ/A/m/cycle.

### Example 3

An oxide superconducting wire in Example 3 was produced using the same method and same condition as those used in Example 1, except that 19 single-filament superconducting wires each having a diameter of 5.3 mm were housed in the second metal sheath so that the average cross-sectional area per filament could be adjusted to 2% of the cross-sectional area of the entire oxide superconducting wire.

A part of the oxide superconducting wire in Example 3 was cut in a direction perpendicular to the direction of its length. The cut section showed a structure in which the filaments were embedded in the matrix made of silver and each filament was surrounded by the barrier layer.

A measurement made on the section showed that the cross-sectional area was 0.5 mm². The filaments included in the oxide superconducting wire in Example 3 had an average aspect ratio of more than 10.

The oxide superconducting wire in Example 3 was subjected to measurements of critical current density and AC loss using the same method and same condition as those used in Example 1. The measured results are shown in Table I. As shown in Table I, the oxide superconducting wire in Example 3 has a critical current density of 13 kA/cm² and an AC loss of 11 μJ/A/m/cycle.

### Example 4

An oxide superconducting wire in Example 4 was produced using the same method and same condition as those used in Example 1, except that seven single-filament superconducting wires each having a diameter of 8.5 mm were housed in the second metal sheath so that the average cross-sectional area per filament could be adjusted to 6% of the cross-sectional area of the entire oxide superconducting wire.

A part of the oxide superconducting wire in Example 4 was cut in a direction perpendicular to the direction of its length. The cut section showed a structure in which the filaments were embedded in the matrix made of silver and each filament was surrounded by the barrier layer.

A measurement made on the section showed that the cross-sectional area was 0.5 mm². The filaments included in the oxide superconducting wire in Example 4 had an average aspect ratio of more than 10.

The oxide superconducting wire in Example 4 was subjected to measurements of critical current density and AC loss using the same method and same condition as those used in Example 1. The measured results are shown in Table I. As shown in Table I, the oxide superconducting wire in Example 4 has a critical current density of 12 kA/cm² and an AC loss of 10 μJ/A/m/cycle.

### Comparative Example 1

An oxide superconducting wire in Comparative example 1 was produced using the same method and same condition as those used in Example 1, except that 127 single-filament superconducting wires each having a diameter of 1.7 mm were housed in the second metal sheath so that the average cross-sectional area per filament could be adjusted to 0.15% of the cross-sectional area of the entire oxide superconducting wire.

A part of the oxide superconducting wire in Comparative example 1 was cut in a direction perpendicular to the direction of its length. The cut section showed a structure in which the filaments were embedded in the matrix made of silver and each filament was surrounded by the barrier layer.

A measurement made on the section showed that the cross-sectional area was 0.5 mm². The filaments included in the oxide superconducting wire in Comparative example 1 had an average aspect ratio of more than 10.

The oxide superconducting wire in Comparative example 1 was subjected to measurements of critical current density and AC loss using the same method and same condition as those used in Example 1. The measured results are shown in Table I. As shown in Table I, the oxide superconducting wire in Comparative example 1 has a critical current density of 5 kA/cm² and an AC loss of 24 μJ/A/m/cycle.

### Comparative Example 2

An oxide superconducting wire in Comparative example 2 was produced using the same method and same condition as those used in Example 4, except that the average cross-sectional area per filament was adjusted to 6.5% of the cross-sectional area of the entire oxide superconducting wire by using the second metal sheath having an outer diameter of 36 mm and an inner diameter of 27 mm.

A part of the oxide superconducting wire in Comparative example 2 was cut in a direction perpendicular to the direction of its length. The cut section showed a structure in which the filaments were embedded in the matrix made of silver and each filament was surrounded by the barrier layer.

A measurement made on the section showed that the cross-sectional area was 0.5 mm². The filaments included in the oxide superconducting wire in Comparative example 2 had an average aspect ratio of more than 10.

The oxide superconducting wire in Comparative example 2 was subjected to measurements of critical current density and AC loss using the same method and same condition as those used in Example 1. The measured results are shown in Table I. As shown in Table I, the oxide superconducting wire in Comparative example 2 has a critical current density of 6 kA/cm² and an AC loss of 22 μJ/A/m/cycle.

TABLE I

| | | | | | Comparative | Comparative |
|---|---|---|---|---|---|---|
| | Example 1 | Example 2 | Example 3 | Example 4 | example 1 | example 2 |
| Types of oxide | Bi-2223 | Bi-2223 | Bi-2223 | Bi-2223 | Bi-2223 | Bi-2223 |
| superconductor | | | | | | |
| Cross-sectional area of | 0.5 | 0.5 | 0.5 | 0.5 | 0.5 | 0.5 |
| oxide superconducting | | | | | | |
| wire (mm²) | | | | | | |
| Percentage of average | 0.2 | 1 | 2 | 6 | 0.15 | 6.5 |
| cross-sectional area per | | | | | | |
| filament over | | | | | | |
| cross-sectional area of | | | | | | |
| oxide superconducting | | | | | | |
| wire (%) | | | | | | |
| Aspect ratio | 10< | 10< | 10< | 10< | 10< | 10< |
| Twisting pitch (mm) | 8 | 8 | 8 | 8 | 8 | 8 |
| Presence or absence of | Present | Present | Present | Present | Present | Present |
| barrier layer | | | | | | |
| Critical current density | 11 | 12 | 13 | 12 | 5 | 6 |
| (kA/cm²) | | | | | | |
| AC loss (μJ/A/m/cycle) | 15 | 14 | 11 | 10 | 24 | 22 |

As explained above, the oxide superconducting wires in Examples 1 to 4 have the following features:
(a) the filament having a Bi-2223-based oxide superconductor is embedded in the matrix made of silver,
(b) the cross-sectional area is 0.5 mm² in the cross section perpendicular to the direction of the length of the oxide superconducting wire, and
(c) in the cross section perpendicular to the direction of the length of the oxide superconducting wire, the average cross-sectional area per filament falls in the range of at least 0.2% and at most 6% of the cross-sectional area of the entire oxide superconducting wire.

On the other hand, the oxide superconducting wires in Comparative examples 1 and 2 have values of 0.15% and 6.5%, respectively, in the percentage of the average cross-sectional area per filament over the cross-sectional area of the entire oxide superconducting wire, in the cross section perpendicular to the direction of the length of the oxide superconducting wire. Table I shows that the oxide superconducting wires in Examples 1 to 4 can not only increase the critical current density but also decrease the AC loss in comparison with the oxide superconducting wires in Comparative examples 1 and 2.

In particular, the oxide superconducting wires in Examples 3 and 4 have, in the cross section perpendicular to the direction of their length, an average cross-sectional area per filament that falls in the range of at least 2% and at most 6% of the cross-sectional area of the entire oxide superconducting wire.

Table I shows that they can not only increase the critical current density but also decrease the AC loss, in particular.

### Example 5

A material powder having a powder of a Bi-2223-based oxide superconductor was produced using the same method and same condition as those used in Example 1. The material powder had a powder of a nonsuperconductor in addition to the powder of the Bi-2223-based oxide superconductor. An examination was conducted on the particle diameter of the powder of the nonsuperconductor. The result confirmed that the number of particles in the powder of the nonsuperconductor having a particle diameter of at most 2 μm constitutes at least 95% of the total number of particles in the powder of the nonsuperconductor included in the material powder.

The material powder was filled into a silver tube having an outer diameter of 12 mm and an inner diameter of 10 mm, which was used as the first metal sheath.

The silver tube filled with the powder was processed by drawing until the diameter became 2 mm to produce a single-filament superconducting wire. A barrier layer made of strontium carbonate was formed on the surface of the single-filament superconducting wire. Ninety-one single-filament superconducting wires each having the barrier layer on the surface were housed in a silver tube having an outer diameter of 36 mm and an inner diameter of 27 mm, which was used as the second metal sheath. The silver tube that housed the single-filament superconducting wires was processed by drawing until the diameter became 0.9 mm to produce a multifilament superconducting wire. At this stage, an examination was conducted on the COV, which is the coefficient of variation in the cross-sectional areas of the single-filament superconducting wires in the multifilament superconducting wire. The examination confirmed that the COV was not more than 15%.

The multifilament superconducting wire was subjected to a softening step in which the wire was maintained for one hour in an atmosphere at 250° C. and a subsequent step for twisting the wire. The combination of the steps was repeated until the filaments in the oxide superconducting wire to be obtained in this example had a twisting pitch of 8 mm. The multifilament superconducting wire was further subjected to a softening step in which the wire was maintained for one hour in an atmosphere at 250° C. Then, the wire underwent a step of skin pass and a subsequent step of rolling process, in which the rolling reduction was predetermined to be at most 82%.

The rolled multifilament superconducting wire was heat-treated for 50 hours at 850° C. under a pressure of 200 atmospheres. Thus, a tape-shaped oxide superconducting wire (the oxide superconducting wire in Example 5) was obtained.

A part of the oxide superconducting wire in Example 5 was cut in a direction perpendicular to the direction of its length. The cut section showed a structure in which the filaments were embedded in the matrix made of silver and each filament was surrounded by the barrier layer. A measurement made on the section showed that the cross-sectional area was 0.5 mm².

The thus obtained oxide superconducting wire in Example 5 was subjected to measurements of critical current density and AC loss using the same method and same condition as those used in Example 1. The measured results showed that the oxide superconducting wire in Example 5 has a critical current density of at least 10 kA/cm² and an AC loss of 15 μJ/A/m/cycle.

### Examples 6 to 12

Bi₂O₃, PbO, SrCO₃, CaCO₃ and CuO were used. Powders of them were mixed to achieve the composition ratio Bi:Pb:Sr:Ca:Cu=1.79:0.4:1.96:2.18:3. The mixed powder was treated by heating and pulverization to obtain a material powder having a powder of a Bi-2223-based oxide superconductor. The material powder was filled into a silver tube having an outer diameter of 12 mm and an inner diameter of 10 mm, which was used as the first metal sheath.

The silver tube filled with the powder was processed by drawing until the diameter became 1.5 mm to produce a single-filament superconducting wire. A barrier layer made of strontium carbonate was formed on the surface of the single-filament superconducting wire. Nineteen single-filament superconducting wires each having the barrier layer on the surface were housed in a silver tube having an outer diameter of 12 mm and an inner diameter of 9 mm, which was used as the second metal sheath. The silver tube that housed the single-filament superconducting wires was processed by drawing until the diameter became 0.5 mm to produce a multifilament superconducting wire.

Next, a plurality of multifilament superconducting wires were cut from the produced multifilament superconducting wire. The obtained multiple multifilament superconducting wires were subjected to a softening step in which the wires were maintained for one hour in an atmosphere at 250° C. and a subsequent step for twisting the wires individually. The combination of the steps was repeated until the filaments in the oxide superconducting wire to be produced in each of Examples 6 to 12 had a twisting pitch different from that of the other examples in this group. Thus, a plurality of multifilament superconducting wires were produced.

These multifilament superconducting wires were subjected to a softening step in which the wires were maintained for one hour in an atmosphere at 250° C. Then, the wires underwent a step of skin pass and a subsequent step of rolling process. The rolled multifilament superconducting wires were subjected to the first sintering process in the atmosphere. Then, the wires were rolled again. Subsequently, the wires were heat-treated for 50 hours at 850° C. under a pressure of 200 atmospheres. Thus, the tape-shaped oxide superconducting wires in Examples 6 to 12 having structures shown in Table II were obtained. In spite of the above description, the oxide superconducting wire in Example 12 was not subjected to the softening step and twisting step of the multifilament superconducting wire. Consequently, Table II has no description in the section of the twisting pitch for the wire.

A cross section perpendicular to the direction of the length of the oxide superconducting wire in each of Examples 6 to 12 showed a structure in which the filaments were embedded in the matrix made of silver and each filament was surrounded by the barrier layer.

In the cross section of the oxide superconducting wire in each of Examples 6 to 12, the cross-sectional area was 0.3 mm². In that section, the average cross-sectional area per filament was 1% of the cross-sectional area of the entire oxide superconducting wire. The filaments included in the oxide superconducting wire in each of Examples 6 to 12 had an average aspect ratio of more than 10.

The oxide superconducting wire in each of Examples 6 to 12 was subjected to measurements of critical current density and AC loss using the same method and same condition as those used in Example 1. The measured results are shown in Table II.

TABLE II

| | Example 6 | Example 7 | Example 8 | Example 9 | Example 10 | Example 11 | Example 12 |
|---|---|---|---|---|---|---|---|
| Types of oxide | Bi-2223 | Bi-2223 | Bi-2223 | Bi-2223 | Bi-2223 | Bi-2223 | Bi-2223 |
| superconductor | | | | | | | |
| Cross-sectional area of | 0.3 | 0.3 | 0.3 | 0.3 | 0.3 | 0.3 | 0.3 |
| oxide superconducting | | | | | | | |
| wire (mm²) | | | | | | | |
| Percentage of average | 1 | 1 | 1 | 1 | 1 | 1 | 1 |
| cross-sectional area per | | | | | | | |
| filament over | | | | | | | |
| cross-sectional area of | | | | | | | |
| oxide superconducting | | | | | | | |
| wire (%) | | | | | | | |
| Aspect ratio | 10< | 10< | 10< | 10< | 10< | 10< | 10< |
| Twisting pitch (mm) | 2 | 4 | 5 | 8 | 12 | 20 | — |
| Presence or absence of | Present | Present | Present | Present | Present | Present | Present |
| barrier layer | | | | | | | |
| Critical current density | 10 | 10 | 10 | 10 | 11 | 11 | 12 |
| (kA/cm²) | | | | | | | |
| AC loss (μJ/A/m/cycle) | 9 | 10 | 10 | 15 | 20 | 24 | 26 |

As shown in Table II, the measured results confirmed that the oxide superconducting wires in Examples 6 to 9, which have a twisting pitch of 8 mm or less, can decrease the AC loss in comparison with the oxide superconducting wires in Examples 10 to 12, which have a twisting pitch of more than 8 mm.

The measured results also confirmed that the oxide superconducting wires in Examples 6 to 8, which have a twisting pitch of 5 mm or less, were can decrease the AC loss in comparison with the oxide superconducting wires in Examples 9 to 12, which have a twisting pitch of 8 mm or more.

### Comparative Examples 3 to 8

Bi₂O₃, PbO, SrCO₃, CaCO₃, and CuO were used. Powders of them were mixed to achieve the composition ratio Bi Pb: Sr: Ca: Cu=1.79:0.4:1.96:2.18:3. The mixed powder was treated by heating and pulverization to obtain a material powder having a powder of a Bi-2223-based oxide superconductor. The material powder was filled into a silver tube having an outer diameter of 12 mm and an inner diameter of 10 mm, which was used as the first metal sheath.

The silver tube filled with the powder was processed by drawing until the diameter became 2 mm to produce a single-filament superconducting wire. A barrier layer made of strontium carbonate was formed on the surface of the single-filament superconducting wire. Nineteen single-filament superconducting wires each having the barrier layer on the surface were housed in a silver tube having an outer diameter of 12 mm and an inner diameter of 9 mm, which was used as the second metal sheath. The silver tube that housed the single-filament superconducting wires was processed by drawing until the diameter became 1.8 mm to produce a multifilament superconducting wire.

Next, a plurality of multifilament superconducting wires were cut from the produced multifilament superconducting wire. The obtained multiple multifilament superconducting wires were subjected to a softening step in which the wires were maintained for one hour in an atmosphere at 250° C. and a subsequent step for twisting the wires individually. The combination of the steps was repeated until the filaments in the oxide superconducting wire to be produced in each of Comparative examples 3 to 8 had a twisting pitch different from that of the other comparative examples in this group. Thus, a plurality of multifilament superconducting wires were produced. During this process, when the twisting pitch was intended to be 8 mm or less, the breaking of wire occurred with high frequency, rendering the processing unable to perform.

The multifilament superconducting wires that survived the production process were subjected to a softening step in which the wires were maintained for one hour in an atmosphere at 250° C. Then, the wires underwent a step of skin pass and a subsequent step of rolling process. The rolled multifilament superconducting wires were subjected to the first sintering process in the atmosphere. Then, the wires were rolled again. Subsequently, the wires were heat-treated for 50 hours at 850° C. under a pressure of 200 atmospheres. Thus, the tape-shaped oxide superconducting wires in Comparative examples 6 to 8 having structures shown in Table III were obtained. On the other hand, it was unable to produce the tape-shaped oxide superconducting wires in Comparative examples 3 to 5 because of the frequent occurring of the breaking of wire during the foregoing twisting operation. In addition, because the oxide superconducting wire in Comparative example 8 was not subjected to the softening step and twisting step of the multifilament superconducting wire, Table III has no description in the section of the twisting pitch for the wire.

A cross section perpendicular to the direction of the length of the oxide superconducting wire in each of Comparative examples 6 to 8 showed a structure in which the filaments were embedded in the matrix made of silver and each filament was surrounded by the barrier layer.

In the cross section of the oxide superconducting wire in each of Comparative examples 6 to 8, the cross-sectional area was 0.8 mm². In that section, the average cross-sectional area per filament was 1% of the cross-sectional area of the entire oxide superconducting wire.

The oxide superconducting wire in each of Comparative examples 6 to 8 was subjected to measurements of critical current density and AC loss using the same method and same condition as those used in Example 1. The measured results are shown in Table III. As for the oxide superconducting wires in Comparative examples 3 to 5, because it was unable to produce them, their critical current density and AC loss were unable to measure.

TABLE III

| | Comparative | Comparative | Comparative | Comparative | Comparative | Comparative |
|---|---|---|---|---|---|---|
| | example 3 | example 4 | example 5 | example 6 | example 7 | example 8 |
| Types of oxide | Bi-2223 | Bi-2223 | Bi-2223 | Bi-2223 | Bi-2223 | Bi-2223 |
| superconductor | | | | | | |
| Cross-sectional area of | 0.8 | 0.8 | 0.8 | 0.8 | 0.8 | 0.8 |
| oxide superconducting | | | | | | |
| wire (mm²) | | | | | | |
| Percentage of average | 1 | 1 | 1 | 1 | 1 | 1 |
| cross-sectional area per | | | | | | |
| filament over | | | | | | |
| cross-sectional area of | | | | | | |
| oxide superconducting | | | | | | |
| wire (%) | | | | | | |
| Aspect ratio | 10< | 10< | 10< | 10< | 10< | 10< |
| Twisting pitch (mm) | 2 | 4 | 8 | 12 | 20 | — |
| Presence or absence of | Present | Present | Present | Present | Present | Present |
| barrier layer | | | | | | |
| Critical current density | Immeasurable | Immeasurable | Immeasurable | 12 | 12 | 12 |
| (kA/cm²) | | | | | | |
| AC loss (μJ/A/m/cycle) | Immeasurable | Immeasurable | Immeasurable | 29 | 30 | 31 |

As shown in Table III, the measured results confirmed that the oxide superconducting wires in Comparative examples 6 to 8 have an AC loss larger than that of the oxide superconducting wires in Examples 1 to 12.

### Examples 13 to 18

Oxide superconducting wires in Examples 13 to 18 each having a twisting pitch different from one another were produced using the same method and same condition as those used in Example 1, except that no barrier layer made of strontium carbonate was formed on the surface of the single-filament superconducting wire. As another exception, the oxide superconducting wire in Example 18 was not subjected to the softening step and twisting step of the multifilament superconducting wire. Consequently, Table N has no description in the section of the twisting pitch for the wire.

A cross section perpendicular to the direction of the length of the oxide superconducting wire in each of Examples 13 to 18 showed a structure in which the filaments were embedded in the matrix made of silver and each filament was not surrounded by the barrier layer.

In the cross section of the oxide superconducting wire in each of Examples 13 to 18, the cross-sectional area was 0.5 mm². In that section, the average cross-sectional area per filament was 1% of the cross-sectional area of the entire oxide superconducting wire. The filaments included in the oxide superconducting wire in each of Examples 13 to 18 had an average aspect ratio of more than 10.

The oxide superconducting wire in each of Examples 13 to 18 was subjected to measurements of critical current density and AC loss using the same method and same condition as those used in Example 1. The measured results are shown in Table N.

TABLE IV

| | Example 13 | Example 14 | Example 15 | Example 16 | Example 17 | Example 18 |
|---|---|---|---|---|---|---|
| Types of oxide | Bi-2223 | Bi-2223 | Bi-2223 | Bi-2223 | Bi-2223 | Bi-2223 |
| superconductor | | | | | | |
| Cross-sectional area of | 0.5 | 0.5 | 0.5 | 0.5 | 0.5 | 0.5 |
| oxide superconducting | | | | | | |
| wire (mm²) | | | | | | |
| Percentage of average | 1 | 1 | 1 | 1 | 1 | 1 |
| cross-sectional area per | | | | | | |
| filament over | | | | | | |
| cross-sectional area of | | | | | | |
| oxide superconducting | | | | | | |
| wire (%) | | | | | | |
| Aspect ratio | 10< | 10< | 10< | 10< | 10< | 10< |
| Twisting pitch (mm) | 6 | 8 | 10 | 12 | 20 | — |
| Presence or absence of | Absent | Absent | Absent | Absent | Absent | Absent |
| barrier layer | | | | | | |
| Critical current density | 12 | 13 | 13 | 13 | 13 | 14 |
| (kA/cm²) | | | | | | |
| AC loss (μJ/A/m/cycle) | 14 | 15 | 20 | 20 | 24 | 26 |

As shown in Table IV, the measured results confirmed that the oxide superconducting wires in Examples 13 and 14, which have a twisting pitch of 8 mm or less, can decrease the AC loss in comparison with the oxide superconducting wires in Examples 15 to 18, which have a twisting pitch of more than 8 mm.

### Example 19

An oxide superconducting wire in Example 19 was produced by lapping a polyimide-based tape using a half-lapping method on the surface of the oxide superconducting wire in Example 1. After the entire length of the oxide superconducting wire in Example 19 was confirmed to be insulated with the foregoing tape, a pancake coil was produced.

Conventionally, a pancake coil is produced by winding an insulating sheet together with an oxide superconducting wire to secure the insulation between the oxide superconducting wires. On the other hand, the oxide superconducting wire in Example 19 is provided with the polyimide-based tape lapped on its surface using a half-lapping method. Therefore, it is not necessary to wind an insulating sheet together with the oxide superconducting wire, so that the workability has been improved considerably.

### Example 20

An oxide superconducting wire in Example 20 was produced by bonding a copper tape on both main faces (the surfaces having the largest area) of the oxide superconducting wire in Example 1 in the direction of the length.

When a tensile test was conducted on the oxide superconducting wire in Example 20, the result showed that the wire has a tensile strength at least 1.5 times that of the oxide superconducting wire in Example 1. The increase in tensile strength produces a margin not only in the design of winding tension for a coil winding, which tension is determined by the strength of the oxide superconducting wire, but also in the design of load at the time a superconducting cable is laid. As a result, it becomes possible to conduct a flexible design.

### Example 21

An oxide superconducting wire in Example 21 was produced through the following process. First, a copper tape was bonded on both main faces of the oxide superconducting wire in Example 1 in the direction of the length. Then, the oxide superconducting wire provided with the bonded copper tapes was further provided with two insulating tapes made of polytetrafluoroethylene by bonding them to it in the direction of its length. At this moment, the two insulating tapes were first bonded to its both main faces and then bonded with each other so as to cover the entire surface of the wire, as shown in FIG. 8.

The entire length of the oxide superconducting wire in Example 21 was confirmed to be insulated. When a tensile test was conducted on the oxide superconducting wire in Example 21, the result showed that the wire has a tensile strength at least twice that of the oxide superconducting wire in Example 1.

### Example 22

A superconducting structure in Example 22 was produced by twisting together three oxide superconducting wires in Example 19 while they were being continuously bent edgewise at a bending diameter of 1,000 mm. The superconducting structure in Example 22 was used to produce a solenoid coil. A measurement using a Rogowski coil confirmed that the nonuniform current flow between the three oxide superconducting wires was suppressed.

It is to be considered that the above-disclosed embodiments and examples are illustrative and not restrictive in all respects. The scope of the present invention is shown by the scope of the appended claims, not by the above-described explanations. Accordingly, the present invention is intended to cover all revisions and modifications included within the meaning and scope equivalent to the scope of the claims.

### INDUSTRIAL APPLICABILITY

The present invention can offer the following products and method:
(a) an oxide superconducting wire that can not only increase its critical current density but also decrease its AC loss,
(b) a superconducting structure incorporating the above-described oxide superconducting wire,
(c) a method of producing an oxide superconducting wire, the method being capable of producing the above-described oxide superconducting wire,
(d) a superconducting cable and a superconducting magnet each of which incorporates either the oxide superconducting wire or an oxide superconducting wire produced by the method of producing an oxide superconducting wire, and
(e) a product incorporating the superconducting magnet.

1. An oxide superconducting wire, having the shape of a tape and comprising:
(a) a matrix; and
(b) a plurality of filaments, each of which has a Bi-2223-based oxide superconductor and which are embedded in the matrix;
the oxide superconducting wire having a cross-sectional area of at most 0.5 mm2 in a cross section perpendicular to the direction of its length;
in the cross section of the oxide superconducting wire, the filaments having an average cross-sectional area per filament of at least 0.2% and at most 6% of the cross-sectional area of the oxide superconducting wire.

2. The oxide superconducting wire as defined by claim 1, wherein the filaments have an average aspect ratio of more than 10.

3. The oxide superconducting wire as defined by claim 1, wherein the filaments turn around the longitudinal center axis of the oxide superconducting wire at a twisting pitch of at most 8 mm, the twisting pitch being the pitch at which the filaments turn.

4. The oxide superconducting wire as defined by claim 3, wherein the twisting pitch is at most 5 mm.

5. The oxide superconducting wire as defined by claim 1, wherein a barrier layer is formed between the filaments.

6. The oxide superconducting wire as defined by claim 1, wherein a metal tape is provided on a surface of the matrix.

7. The oxide superconducting wire as defined by claim 1, wherein an insulating film is provided on the surface of the matrix.

8. The oxide superconducting wire as defined by claim 1, wherein:
(a) a metal tape is provided on a surface of the matrix; and
(b) an insulating film is provided on the surface of the metal tape.

9. A superconducting structure, comprising a plurality of oxide superconducting wires as defined by claim 7, the wires being twisted together;
in which superconducting structure, the together-twisted oxide superconducting wires include at least one oxide superconducting wire that is bent edgewise.

10. A superconducting structure, comprising:
(a) a plurality of oxide superconducting wires as defined by claim 1;
(b) a tape-shaped protective film which has two opposing main faces and in which the multiple oxide superconducting wires are placed; and
(c) a metal tape that is provided on each of the opposing main faces.

11. The superconducting structure as defined by claim 10, wherein a high-resistivity body that has a resistivity higher than that of the protective film is placed between the neighboring oxide superconducting wires.

12. A superconducting structure, comprising:
(a) a plurality of oxide superconducting wires as defined by claim 1; and
(b) a tape-shaped insulating protective film in which the multiple oxide superconducting wires are placed.

13. A method of producing an oxide superconducting wire, the method comprising the steps of:
(a) filling a first metal sheath with a material powder including both a powder of an oxide superconductor and a powder of a nonsuperconductor;
(b) processing the first metal sheath filled with the material powder by drawing to form a single-filament superconducting wire;
(c) housing a plurality of single-filament superconducting wires described above into a second metal sheath;
(d) processing the second metal sheath that houses the single-filament superconducting wires by drawing to form a multifilament superconducting wire;
(e) processing the multifilament superconducting wire by rolling; and
(f) heat-treating the rolled multifilament superconducting wire;
in which method:
(g) in the material powder, the number of particles in a powder of a nonsuperconductor having a particle diameter of at most 2 μm constitutes at least 95% of the total number of particles in the powder of the nonsuperconductor;
(h) the cross-sectional areas of the single-filament superconducting wires in the multifilament superconducting wire before being processed by rolling have a coefficient of variation (COV) of at most 15%;
(i) the step of processing the multifilament superconducting wire by rolling is performed at a rolling reduction of at most 82%; and
(j) the step of heat-treating the rolled multifilament superconducting wire is performed under a pressure of at least 200 atmospheres.

14. The method of producing an oxide superconducting wire as defined by claim 13, the method further comprising a step of twisting the multifilament superconducting wire before the step of processing the multifilament superconducting wire by rolling, the step of twisting being performed a plurality of times.

15. The method of producing an oxide superconducting wire as defined by claim 13, the method further comprising a step of forming a barrier layer in the oxide superconducting wire.

16. A superconducting cable, comprising a member selected from the group consisting of:
(a) the oxide superconducting wire as defined by claim 1;
(b) the superconducting structure as defined by claim 9; and
(c) an oxide superconducting wire produced by the method of producing an oxide superconducting wire as defined by claim 13.

17. A superconducting magnet, comprising a member selected from the group consisting of:
(a) the oxide superconducting wire as defined by claim 1;
(b) the superconducting structure as defined by claim 9; and
(c) an oxide superconducting wire produced by the method of producing an oxide superconducting wire as defined by claim 13.

18. A motor armature, comprising the superconducting magnet as defined by claim 17.

19. A refrigerator-cooled-type magnet system, comprising the superconducting magnet as defined by claim 17.

20. An MRI, comprising the superconducting magnet as defined by claim 17.
